(19) United States
(12) Patent Application Publication
(10) Pub. No.: US 2017/0229594 A1
(43) Pub. Date: Aug. 10, 2017

(54) LIGHT DIFFUSION MEMBER FOR INTERCONNECTORS, INTERCONNECTOR FOR SOLAR CELLS PROVIDED WITH SAME, AND SOLAR CELL MODULE

(71) Applicant: TOYO ALUMINIUM KABUSHIKI KAISHA, Osaka-shi, Osaka (JP)

(72) Inventors: Takaaki Fujino, Osaka (JP); Daisuke Maeda, Osaka (JP); Takanobu Terasawa, Osaka (JP)

(73) Assignee: TOYO ALUMINIUM KABUSHIKI KAISHA, Osaka-shi, Osaka (JP)

(21) Appl. No.: 15/503,074

(22) PCT Filed: Aug. 17, 2015
(86) PCT No.: PCT/JP2015/073004

§ 371 Date: Feb. 10, 2017

(30) Foreign Application Priority Data
Aug. 21, 2014 (JP) 2014-168694

(51) Int. Cl. H01L 31/05; H01L 31/054; H01L 31/055

(52) U.S. Cl. CPC H01L 31/0512; H01L 31/055; H01L 31/0543

(57) ABSTRACT

This invention provides a light diffusion member for an interconnector that enables the amount of light incident on the surface of a solar cell to be increased compared with the related art and achieves excellent power generation efficiency, and an interconnector for solar cells that comprises the light diffusion member.

The light diffusion member for an interconnector 3 is disposed on the surface of an interconnector 1 for connecting adjacent solar cells 6 opposite to the solar cells 6, and the light diffusion member comprises a light diffusion layer 3a containing a resin and inorganic particles.

### TECHNICAL FIELD

The present invention relates to a light diffusion member for an interconnector that can be applied to, for example, crystalline silicon solar cells, an interconnector for solar cells that comprises the light diffusion member, and a solar cell module.

### BACKGROUND ART

Interconnectors for solar cells are wiring members for electrically connecting adjacent solar cells to collect current in, for example, crystalline silicon solar cells. This wiring member is composed of a substrate whose entire surface is coated with solder and is formed by subjecting a rectangular metal substrate made of copper or the like to under plating, and coating the entire surface of the rectangular metal substrate by molten solder plating.

A known example of the substrate whose entire surface is coated with solder is a member obtained by plating the surface of a rectangular copper substrate with Sn—Bi—Ag-based solder. A technique of applying this member to an interconnector for solar cells has been proposed (see, for example, PTL 1). However, since such an interconnector for solar cells is composed of a rectangular metal substrate, light is blocked due to the shade of the interconnector portion, resulting in reduced power generation efficiency of solar cells. Moreover, the solder-plated metal itself absorbs visible light, causing a reduction in reflected light. There is thus a drawback in that incident light cannot be effectively utilized. In view of this, various techniques have been proposed to improve power generation efficiency of solar cells. For example, a method in which light is allowed to efficiently be incident on the surface of solar cells (absorbers) by patterning an interconnector for solar cells with grooves having a face angle of 60 degrees so that light reflected by the interconnector undergoes total internal reflection in the glass-air interface has been proposed (see, for example, PTL 2). In this case, a rectangular tinned-copper substrate is patterned with grooves by using a diamond-turned mandrel rolling technique.

### CITATION LIST

### Patent Literature

PTL 1: JP2002-217434A

PTL 2: JP2009-518823A

### SUMMARY OF INVENTION

### Technical Problem

With the above method, light reflected by the interconnector for solar cells can be effectively utilized; however, since the patterned solder-plated metal itself absorbs visible light, reflected light is reduced to about 80%. There is thus still room for improvement in the power generation efficiency of solar cells. In addition, the above technique requires a separate step of patterning, thus complicating the production process.

The present invention was made in view of the above problems. An object of the present invention is to provide a light diffusion member for an interconnector that enables the amount of light incident on the surface of a solar cell to be increased compared with the related art and achieves excellent power generation efficiency, and an interconnector for solar cells that comprises the light diffusion member. Another object of the present invention is to provide a solar cell module comprising the interconnector for solar cells.

### Solution to Problem

The present inventors conducted extensive research to achieve the above objects, and found that when an interconnector for solar cells is provided with a light diffusion layer containing a resin and inorganic particles, the above objects can be achieved. The present invention has been accomplished based on this finding.

More specifically, the present invention relates to the following light diffusion member for an interconnector, interconnector for solar cells, and solar cell module.

1. A light diffusion member for an interconnector for connecting adjacent solar cells, the member being disposed on a surface of the interconnector opposite to the solar cells, and the member comprising a light diffusion layer containing a resin and inorganic particles.
2. The light diffusion member for an interconnector according to Item 1, wherein the average absorptivity of visible light in the wavelength range of 400 nm or more but 800 nm or less is 10% or less, and the light diffusivity is 90% or more, the light diffusivity being defined by a value obtained by dividing an average value of an L* value measured at a reflection angle of 45 degrees when the incidence angle is 45 degrees and an L* value measured at a reflection angle of 75 degrees when the incidence angle is 45 degrees by an L* value measured at a reflection angle of 15 degrees when the incidence angle is 45 degrees.
3. The light diffusion member for an interconnector according to Item 1 or 2, wherein the resin comprises at least one member selected from the group consisting of ionomers, ethylene-vinyl acetate copolymers, ethylene-vinyl (meth)acrylate copolymers, adhesive polyolefin resins, acrylic resins, urethane resins, silicone resins, and unsaturated polyester resins.
4. The light diffusion member for an interconnector according to any one of Items 1 to 3, wherein the light diffusion layer further contains a phosphor.
5. An interconnector for solar cells, the interconnector comprising the light diffusion member for an interconnector according to any one of Items 1 to 4.
6. A solar cell module comprising the interconnector for solar cells according to Item 5.

### Advantageous Effects of Invention

Since the light diffusion member for an interconnector according to the present invention has excellent light reflection and diffusion performance, the power generation efficiency of a solar cell module can be increased by disposing the light diffusion member on the surface of an interconnector for solar cells on the side opposite to the solar cell side. More specifically, light incident on the solar cell module is diffused and reflected by the light diffusion member for an interconnector, and the diffused and reflected light is reflected by the glass of the solar cell module front surface and is incident on the solar cells. As a result, the amount of light incident on the solar cells is increased, resulting in improved power generation efficiency.

Since the interconnector for solar cells according to the present invention comprises the above light diffusion member for an interconnector, use of the interconnector in a solar cell module makes it possible to improve the power generation efficiency of the solar cells.

Moreover, the solar cell module according to the present invention comprises the above interconnector for solar cells and thus has excellent power generation efficiency.

### BRIEF DESCRIPTION OF DRAWINGS

FIG. 1 is a schematic cross-sectional view showing an example of an embodiment of a solar cell module comprising the light diffusion members for interconnectors of the present invention.

FIG. 2 is a plan view of a solar cell module with no light diffusion member for an interconnector, and a schematic diagram showing a state where solar cells are connected via interconnectors.

FIG. 3 is a cross-sectional view of the same solar cell module as shown in FIG. 2, and a cross-sectional view, of the solar cell module, taken along line a-a in FIG. 2.

FIG. 4 is a plan view showing an example of an embodiment of a solar cell module comprising the light diffusion members for interconnectors of the present invention, and a schematic diagram showing a state where interconnectors are provided with the light diffusion members.

FIG. 5 is a cross-sectional view of the same solar cell module as shown in FIG. 4, and a cross-sectional view, of the solar cell module, taken along line b-b in FIG. 4.

FIG. 6 is a plan view showing an example of another embodiment of a solar cell module comprising the light diffusion members for interconnectors of the present invention, and a schematic diagram showing a state where interconnectors are provided with the light diffusion members.

### DESCRIPTION OF EMBODIMENTS

Embodiments of the present invention are described below in detail.

FIG. 1 is a schematic cross-sectional view showing an example of an embodiment of a solar cell module A comprising light diffusion members for interconnectors 3. The solar cell module A of this embodiment comprises solar cells 6, interconnectors 1, light diffusion members for interconnectors 3, toughened glass 7, a sealing member 8, and a rear surface protection sheet 9.

Each solar cell 6 is a member having the function of generating power through photoelectric conversion of received light. The solar cell module A generally comprises a plurality of solar cells 6.

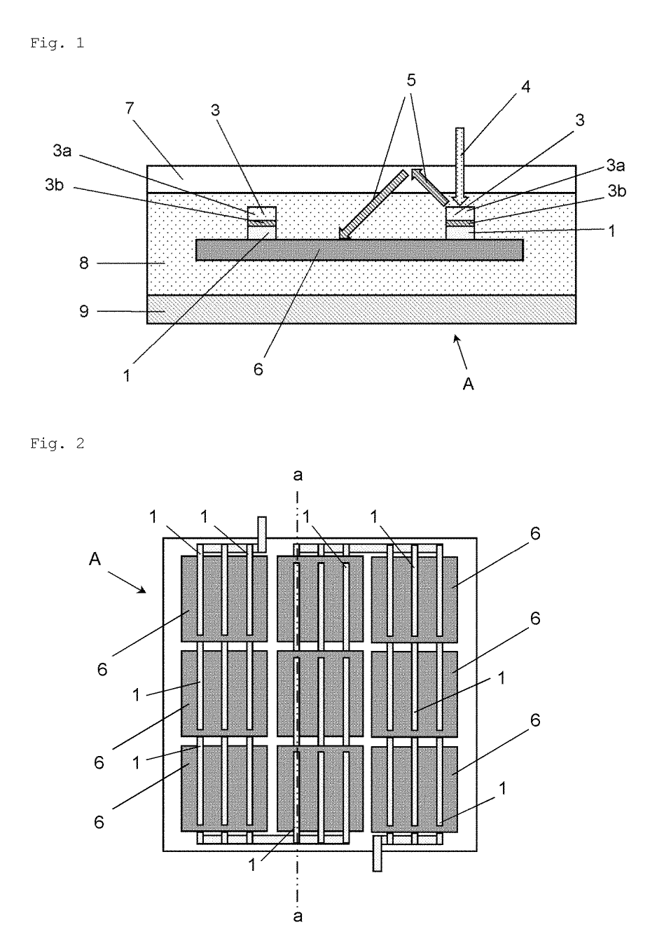

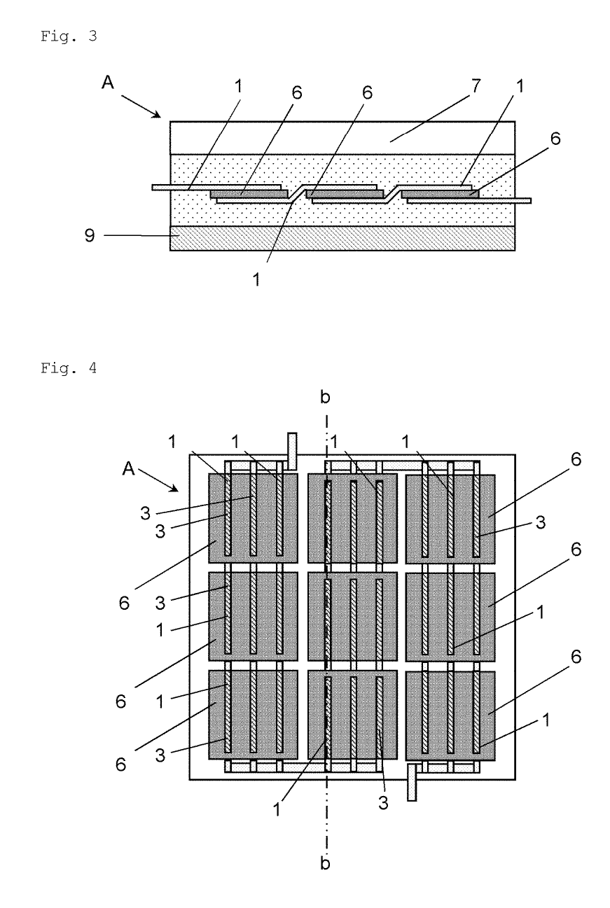

FIGS. 2 and 3 are respectively a plan view and a cross-sectional view of a solar cell module with no light diffusion member for an interconnector 3. In FIG. 2, the toughened glass 7 and the sealing member 8 are omitted. FIG. 3 is a cross-sectional view taken along line a-a in FIG. 2. In FIG. 3, the cross-sectional view is shown, including the toughened glass 7 and the sealing member 8.

As can be seen from FIGS. 2 and 3, a plurality of solar cells 6 is placed in the vertical and the horizontal directions at predetermined intervals, i.e., arranged in a lattice pattern, over the substantially entire surface in the solar cell module A.

Each interconnector 1 is a member for electrically connecting adjacent solar cells that is formed, for example, like a long ribbon as shown in FIGS. 2 and 3 and is electrically conductive. One end of the interconnector 1 is joined to the front surface of one of adjacent solar cells 6, and the other end of the interconnector 1 is joined to the rear surface of the other solar cell 6, thereby electrically coupling the solar cells 6 to each other. In currently widely used monofacial P-type silicon solar cells, the light-receiving surface is a negative electrode, and the non-light-receiving surface is a positive electrode. As shown in FIGS. 2 and 3, the interconnectors 1 are generally joined in series via the light-receiving surfaces and the non-light-receiving surfaces of the solar cells 6.

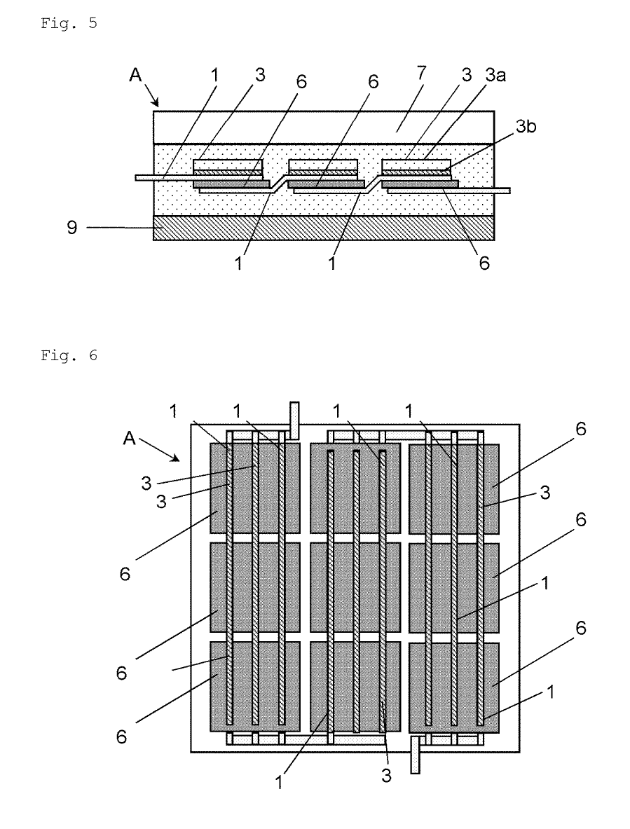

FIGS. 4 and 5 are respectively a plan view and a cross-sectional view of a solar cell module comprising light diffusion members for interconnectors 3. In FIG. 4, the toughened glass 7 and the sealing member 8 are omitted. FIG. 5 is a cross-sectional view taken along line b-b in FIG. 4. In FIG. 5, the cross-sectional view is shown, including the toughened glass 7 and the sealing member 8.

The light diffusion members for interconnectors 3 (which hereinafter may be abbreviated as “light diffusion members 3”) are disposed on the surfaces of the interconnectors 1 on the side that is opposite to the solar cell 6 side. More specifically, the light diffusion members 3 are disposed on the sunlight-receiving side of the interconnectors 1. Each light diffusion member 3 is a member having the function of diffusing incident light and the function of reflecting incident light. The detailed configuration of the light diffusion members 3 is described below.

As shown in FIGS. 4 and 5, one light diffusion member 3 can be disposed per interconnector. By doing so, good productivity can be achieved in the general production process for automatic interconnector wiring.

As shown in FIG. 6, one light diffusion member 3 that is in a long sheet form may be disposed per cell string, not per interconnector. In this case, however, because of the long sheet, it is necessary to carry out alignment of interconnectors at one time. Thus, the light diffusion members 3 are preferably disposed in a predetermined length for the solar cells 6, as described above, from the viewpoint of the production process.

The sealing member 8 is provided for integrating a plurality of solar cells 6 and a plurality of interconnectors 1 by sealing them. Due to this, the solar cells 6 are fixed in the solar cell module A. The toughened glass 7 is attached to the front surface side of the sealing member 8, i.e., the sunlight-receiving surface. The rear surface protection sheet 9 is attached to the rear surface side of the sealing member 8.

In the solar cell module A of the embodiment of FIG. 1, after sunlight is incident from the toughened glass 7 side, the solar cells 6 receive the light and generate power through photoelectric conversion.

In particular, in the solar cell module A of this embodiment, “incident light 4,” which is light incident on the interconnector 1 portions, is diffused and reflected by the light diffusion members 3. The diffused and reflected light 5 is reflected by the toughened glass 7 and then received by the solar cells 6. Such incident light diffusion and reflection effects of the light diffusion members 3 increase the amount of light incident on the solar cells 6 as a whole, resulting in improved power generation efficiency in the solar cell module A.

The light diffusion members 3 are described in detail below.

Each light diffusion member 3 is formed such that the light diffusion member 3 comprises a light diffusion layer 3a containing at least a resin and inorganic particles (see FIG. 1). More specifically, the light diffusion member 3 is formed such that the light diffusion member 3 comprises a light diffusion layer 3a containing a resin as a matrix component and inorganic particles in the matrix component. As shown in the embodiment of FIG. 1, the light diffusion member 3 may comprise an adhesion layer 3b for adhering to the interconnector 1, in addition to the light diffusion layer 3a.

The light diffusion layer 3a may be formed from a resin film, resin sheet, or resin plate (these may be collectively referred to as “resin molded article”) containing inorganic particles.

When the light diffusion layer 3a is a resin molded article containing inorganic particles, the type of resin is not particularly limited, and known resins can be used. Specific examples of resins include polyolefin resins, such as high-density polyethylene, low-density polyethylene, linear low-density polyethylene, polypropylene resins, and other polybutenes; acrylic resins, methacrylic resins, polyvinyl chloride resins, polystyrene resins, polyvinylidene chloride resins, ethylene-vinyl acetate copolymer saponification products, polyvinyl alcohol resins, polycarbonate resins, fluororesins (e.g., polyvinylidene fluoride, polyvinyl fluoride, and ethylene-tetrafluoroethylene), polyvinyl acetate resins, acetal resins, polyester resins (e.g., polyethylene terephthalate, polybutylene terephthalate, and polyethylene naphthalate), polyamide resins, polyphenylene ether resins, and the like. Of these, high-density polyethylene, low-density polyethylene, linear low-density polyethylene, polypropylene resins, and acrylic resins are preferable since they have excellent moldability and desired diffusion and reflection performance is easily obtained. The light diffusion layer 3a may contain one or more types of resins. When two or more types of resins are contained in the light diffusion layer 3a, they may be in the form of a polymer blend, a polymer alloy, or a polymer composite. The resins may be copolymers or graft polymers.

The resin film or resin sheet may be, for example, stretched uniaxially or biaxially. Regarding the type of resin used when the resin film or resin sheet is formed so, high-density polyethylene, low-density polyethylene, linear low-density polyethylene, or polypropylene is preferably used as a main component since excellent weather resistance and excellent moisture heat resistance can be imparted to the solar cell module A. As the method for molding the resin molded article, T-die molding or inflation molding can be used. The resin molded article can also be molded with a multilayer extruder. The molecular weight etc., of the resin plate are not particularly limited as long as molding is possible.

The inorganic particles are important material for imparting a light diffusion function and a light reflection function to the light diffusion layer 3a. The type of inorganic particles is not particularly limited. Examples include titanium oxide, silica, aluminum oxide, barium sulfate, germanium, zinc oxide, zinc sulfide, zinc carbonate, zirconium oxide, calcium carbonate, calcium fluoride, lithium fluoride, antimony, magnesium oxide, vanadium oxide, tantalum oxide, cerium oxide, and the like. Mica, titanated mica, talc, clay, kaolin, etc., can also be used. These may be used singly or in a combination of two or more. The inorganic particles may also be in the form of a composite oxide composed of oxides of a plurality of elements. In addition, the surface of the inorganic particles may further be coated with other inorganic fine particles or organic fine particles.

As the inorganic particles, it is particularly preferable to use titanium oxide from the viewpoint of high refractive index, low conductivity, moisture heat resistance, stability over time, costs, etc. There is no particular limitation on the type of titanium oxide, and rutile-type titanium oxide, anatase-type titanium oxide, etc. can be used. Rutile-type titanium oxide is preferable since it can impart excellent light diffusion properties and remains stable over a long period of time.

The average particle diameter of the inorganic particles is not particularly limited and can be, for example, 200 nm or more but 300 nm or less. When the average particle diameter is 200 nm or more, the reflectance in the near-infrared light wavelength range of 800 to 1200 nm, which contributes to power generation of the solar cell module A, can be increased, resulting in higher power generation efficiency. In addition, when the average particle diameter is 200 nm or more, the catalytic activation by the inorganic particles can be suppressed, and thus resin degradation is less likely to occur. On the other hand, when the average particle diameter is 300 nm or less, the reflectance in the visible light range of 400 to 800 nm, which greatly contributes to power generation of the solar cell module A, can be increased, resulting in higher power generation efficiency. Light in the visible light region of 400 to 800 nm is known to have higher energy density than light in the long wavelength region of 800 to 1200 nm by Planck's law, and is thus particularly advantageous in power generation of solar cells made of crystalline silicon or the like. Therefore, an average particle diameter of 300 nm or less is particularly preferable since the power generation efficiency of the solar cell module A is further increased. To even further increase the power generation efficiency of the solar cell module A, the average particle diameter of the inorganic particles is more preferably 210 nm or more but 290 nm or less. “Average particle diameter” as used herein refers to the primary particle diameter of the inorganic particles, i.e., the average value obtained by measuring the particle diameters of a total of 10 samples of randomly selected primary particles by electron microscope observation.

Since the light diffusion function of the light diffusion layer 3a is known to heavily depend on the difference in refractive index between the resin and the inorganic particles and the particle diameter of the inorganic particles, a combination of the resin and the inorganic particles may be selected according to the desired light diffusion function.

The inorganic particles are present in the resin used as a matrix. The method for allowing the inorganic particles to be present in the resin is not particularly limited. For example, a resin molded article containing inorganic particles can be obtained by mixing the resin and the inorganic particles as starting materials in advance and molding a resin molded article.

To facilitate dispersion of the inorganic particles in the resin, the inorganic particles can also be coated with, for example, a fatty acid such as stearic acid, or a polyol, which is a polyhydric alcohol. In this case, since the dispersibility of the inorganic particles in the resin is improved, the reflectance in the light diffusion layer 3a can be enhanced, which contributes to improvement in the power generation efficiency of the solar cell module A. The coating method is not particularly limited, and a known method can be used.

The content of the inorganic particles is preferably 5.0 mass % or more but 60.0 mass % or less relative to the total mass of the light diffusion layer 3a. When the content of the inorganic particles is 5.0 mass % or more, the effect of the inorganic particles added can sufficiently be achieved. When the content of the inorganic particles is 60.0 mass % or less, the tensile strength and tear strength of the light diffusion layer 3a itself can be prevented from decreasing. The content of the inorganic particles is more preferably 10.0 mass % or more but 50.0 mass % or less relative to the total mass of the light diffusion layer 3a.

The light diffusion layer 3a containing the resin and the inorganic particles may have single layer structure or a multilayer structure that is formed by stacking a plurality of layers. When the light diffusion layer 3a has a multilayer structure, all of the layers may be formed from the same material or different materials. In particular, when the light diffusion layer 3a has a multilayer structure, the type, particle diameter, content, etc., of inorganic particles added to each layer may vary between the layers.

The thickness of the light diffusion layer 3a is not particularly limited and can be, for example, 20 to 200 μm. A thickness of the light diffusion layer 3a of 20 μm or more reduces the probability that the incident light 4 reaches, and is absorbed by, the interconnector 1, thus enabling more effective use of the incident light 4. A thickness of the light diffusion layer 3a of 200 μm or less facilitates prevention of damage of the solar cells 6 during vacuum lamination step in the production of the solar cell module A. The thickness of the light diffusion layer 3a is more preferably 30 to 180 μm, and particularly preferably 50 to 150 μm. Here, the thickness of the light diffusion layer 3a refers to the overall thickness of the light diffusion layer 3a. When the light diffusion layer 3a has a multilayer structure, the thickness of the light diffusion layer 3a refers to the sum of the thicknesses of the layers.

The light diffusion layer 3a contains the resin and the inorganic particles and may contain additives, such as antioxidants and ultraviolet absorbers, as long as the light diffusion function of the light diffusion layer 3a is not impaired.

In particular, the light diffusion layer 3a can also contain a phosphor. Examples of the phosphor include wavelength conversion particles, which are phosphor particles that can absorb ultraviolet light in the wavelength range of 300 to 400 nm and convert it into the visible light spectrum having a specific excitation peak in the wavelength range of 400 to 800 nm. When the light diffusion layer 3a contains the phosphor, ultraviolet light, which is not inherently used for power generation, is converted into visible light, thus further improving the power generation efficiency of the cells.

When the light diffusion layer 3a contains the phosphor, a preferable embodiment of the light diffusion member 3 is as follows: the light diffusion layer 3a is formed to have a multilayer structure with two or more layers as described above in which a layer containing mainly phosphor particles is formed, as its outermost layer, on the side opposite to the solar cell. With the light diffusion members 3 of this embodiment, visible light obtained by wavelength conversion of incident ultraviolet light, and incident visible light can effectively be diffused and reflected to allow them to be incident on the solar cells 6.

Examples of usable phosphor particles include inorganic phosphors in which a rare earth element, such as yttrium, europium, or terbium, is added to an oxide, such as aluminum oxide; organic phosphors, such as cyanine dyes; rare earth metal complexes in which an organic compound, such as alkyl group, is coordinated to a rare earth metal; and the like. Of these, rare earth metal complexes are preferable from the viewpoint of the wavelength conversion efficiency and long-term stability. The content of the phosphor particles is preferably 0.1 mass % or more but 10.0 mass % or less relative to the total mass of the light diffusion layer 3a. When the content of the phosphor particles is 0.1 mass % or more, the effect of the phosphor particles added can sufficiently be achieved. When the content of the phosphor particles is 10.0 mass % or less, the tensile strength and tear strength of the light diffusion layer 3a itself can be prevented from decreasing.

The light diffusion member 3 can comprise an adhesion layer 3b in addition to the light diffusion layer 3a. As shown in FIG. 1, the adhesion layer 3b is stacked on the rear surface side of the light diffusion layer 3a, i.e., on the surface of the light diffusion layer 3a on the solar cell 6 side. When the light diffusion member 3 comprises the adhesion layer 3b, the light diffusion member 3 is easily adhered to the interconnector 1, resulting in good adhesion between the light diffusion member 3 and the interconnector 1.

In this case, the adhesion layer 3b can be formed using a resin exhibiting good adhesion to the interconnector 1 and the light diffusion layer 3a. Examples of resins usable for forming the adhesion layer 3b includes adhesive polyolefins, such as polyethylene and polypropylene having adhesive properties; ethyl cellulose, nitrocellulose, polyvinyl butyral, phenolic resins, melanin resins, urea resins, xylene resins, alkyd resins, unsaturated polyester resins, (meth)acrylic resins, polyimide resins, furan resins, urethane resins, epoxy resins, isocyanate compounds, cyanate compounds, and like thermosetting resins, polystyrenes, ABS resins, polymethyl methacrylate, polyvinyl chloride, polyvinylidene chloride, polyvinyl acetate, polyvinyl alcohol, polyacetals, polycarbonates, polyethylene terephthalate, polybutylene terephthalate, polyphenylene oxide, polysulfones, polyimides, polyethersulfones, polyarylates, polyetheretherketones, polytetrafluoroethylene, silicone resins, ionomer resins, ethylene-vinyl acetate copolymers, and the like. These resins may be used singly or in a combination of two or more. Of the resins described above, ionomer resins, ethylene-vinyl acetate copolymers, ethylene-(meth)acrylic acid copolymers, adhesive polyolefin resins, acrylic resins, urethane resins, silicone resins, and unsaturated polyester resins are preferable in view of good adhesion to the interconnector 1. The adhesive polyolefin resins refer to modified resins in which a reactive functional group is grafted to a polyolefin resin. Examples of reactive functional groups include unsaturated carboxylic acids. Examples of such adhesive polyolefin resins include graft modified polyethylene resins; graft modified ethylene-ethyl acrylate copolymer resins; graft modified ethylene-vinyl acetate copolymer resins; graft modified polypropylene resins; resins obtained by graft-modifying an α-olefin, such as polybutene-1 or poly-4-methylpentene-1, or an ethylene-α-olefin copolymer resin with, for example, an unsaturated carboxylic acid; and the like. Specific examples of commercially available products of adhesive polyolefin resins include Admer (registered trademark), which is an adhesive polyolefin produced by Mitsui Chemicals, Inc., more specifically, Admer LF128 (registered trademark), and the like. The ionomer resins described above are a general term for polymer metal salt having, as polymer side-chains, acidic groups, such as carboxylic acid and sulfonic acid groups, some or all of which have been converted into metal salt. In the present invention, the type of ionomer resin is not particularly limited as long as the ionomer resin falls within this definition.

The adhesion layer 3b can be formed by applying an adhesive or a pressure-sensitive adhesive to the light diffusion layer 3a. The adhesion layer 3b can also be formed by applying a pressure-sensitive adhesive processed in advance into the form of a film or a tape. The adhesive and pressure-sensitive adhesive are preferably formed from the resins described above. The adhesive and pressure-sensitive adhesive are each particularly preferably formed from an acrylic resin, a urethane resin, a silicone resin, or an unsaturated polyester resin, from the viewpoint of weather resistance.

When the light diffusion member 3 comprises the light diffusion layer 3a and the adhesion layer 3b, the light diffusion member 3 have both the light diffusion function and the function of adhering to the interconnector. Such a light diffusion member 3 can be obtained by, for example, two-layer coextrusion, i.e., coextruding the light diffusion layer 3a and the adhesion layer 3b. A known method can be used for the two-layer coextrusion. The two-layer coextrusion can be generally performed by a method similar to a method for producing a multilayer film.

The light diffusion member 3 does not necessarily comprise the adhesion layer 3b and may consist of the light diffusion layer 3a. In this case, a resin having adhesive properties is preferably further added to the resin constituting the light diffusion layer 3a to impart, to the light diffusion layer 3a, adhesiveness to the interconnector 1. Examples of resins having adhesive properties include materials that are the same as the resins usable for the adhesion layer 3b mentioned above. Specific examples of resins having adhesive properties include modified polyolefin resins and ionomer resins having adhesive properties, such as Admer (registered trademark), which is an adhesive polyolefin produced by Mitsui Chemicals, Inc.

The light diffusion member 3 is disposed on the surface of the interconnector 1 on the side opposite to the solar cell 6. The light diffusion member 3 may be disposed on the entire or part of the surface of the interconnector 1. To further improve the power generation efficiency of the solar cell module A, the light diffusion member 3 is preferably formed on the entire surface of the interconnector 1.

Like the embodiment shown in FIG. 1, in the solar cell module A comprising the interconnectors 1 provided with the light diffusion members 3, incident light 4 incident from the toughened glass 7 is diffused and reflected by the light diffusion members 3. The diffused and reflected light 5 is reflected again by the toughened glass 7 and is incident on the solar cells 6. As a result, the amount of light incident on the solar cells 6 is increased. As described above, since the solar cell module A comprises the interconnectors 1 provided with the light diffusion members 3, which have excellent light reflection and diffusion performance, incident sunlight can more effectively be used, thus increasing the power generation efficiency of the solar cell module A.

In the light diffusion member 3, the average absorptivity of visible light in the wavelength range of 400 nm or more but 800 nm or less is preferably 10% or less, and the light diffusivity is preferably 90% or more. When the average absorptivity of visible light in the wavelength range of 400 nm or more but 800 nm or less is 10% or less, the visible light reflection performance of the light diffusion member 3 is further increased, thus enabling high power generation efficiency to be imparted to the solar cell module A. When the light diffusivity is 90% or more, the light diffusion member 3 has excellent light diffusion performance, thus enabling high power generation efficiency to be imparted to the solar cell module A. The light diffusivity as used herein is defined by a value obtained by dividing the average value of the L* value measured at a reflection angle of 45 degrees when the incidence angle is 45 degrees and the L* value measured at a reflection angle of 75 degrees when the incidence angle is 45 degrees by the L* value measured at a reflection angle of 15 degrees when the incidence angle is 45 degrees. The average absorptivity of visible light in the light diffusion member 3 can be measured with a commercially available spectroscope, for example, a V-570 produced by JASCO Corporation, and the light diffusivity can be measured with a commercially available multi-angle spectrophotometer, for example, an MA68IINS multi-angle spectrophotometer produced by X-Rite Inc. It can be said that the light diffusivity is an index indicating the degree of light expansion.

In the embodiment of FIG. 1, the light diffusion layer 3a is formed from a resin molded article, such as a resin film, as described above, but it is not limited to this. For example, the light diffusion layer 3a may be formed in the form of a coating film obtained using an ink composition.

The ink composition comprises a liquid containing a resin and the inorganic particles described above.

As the resin in the ink composition, a known resin can be used. Examples include ethyl cellulose, nitrocellulose, polyvinyl butyral, phenolic resins, melanin resins, urea resins, xylene resins, alkyd resins, unsaturated polyester resins, acrylic resins, polyimide resins, furan resins, urethane resins, epoxy resins, isocyanate compounds, cyanate compounds, and like thermosetting resins, polyethylene, polypropylene, polystyrenes, ABS resins, polymethyl methacrylate, polyvinyl chloride, polyvinylidene chloride, polyvinyl acetate, polyvinyl alcohol, polyacetals, polycarbonates, polyethylene terephthalate, polybutylene terephthalate, polyphenylene oxide, polysulfones, polyimides, polyethersulfones, polyarylates, polyetheretherketones, polytetrafluoroethylene, silicone resins, and the like. These resins can be used singly or in a combination of two or more.

When the main component of the resin is a curable resin, such as a mixture of an acrylic acid ester monomer and an epoxy resin, the ink composition may further contain a curing agent typified by an amine compound.

The resin in the ink composition may be dissolved or dispersed in a solvent. Examples of solvents include diethylene glycol monobutyl ether, diethylene glycol monobutyl ether acetate, dipropylene glycol monomethyl ether, and the like. Known organic solvents can also be used.

The ink composition may contain additives. Examples of additives include leveling agents, antioxidants, corrosion inhibitors, antifoaming agents, thickeners, tackifiers, coupling agents, static-electricity-imparting agents, polymerization inhibitors, thixotropic agents, antisettling agents, and the like. Specific examples include polyethylene glycol ester compounds, polyethylene glycol ether compounds, polyoxyethylene sorbitan ester compounds, sorbitan alkyl ester compounds, aliphatic polycarboxylic acid compounds, phosphoric acid ester compounds, amideamine salts of polyester acids, polyethylene oxide compounds, fatty acid amide waxes, and the like.

The content of the inorganic particles is preferably 5.0 mass % or more but 60.0 mass % or less relative to the total mass of the ink composition. When the content of the inorganic particles is 5.0 mass % or more, the effect of the inorganic particles added can be sufficiently achieved. When the content of the inorganic particles is 60.0 mass % or less, the tensile strength and tear strength of the light diffusion layer 3a itself can be prevented from decreasing. The content of the inorganic particles is more preferably 10.0 mass % or more but 50.0 mass % or less relative to the total mass of the light diffusion layer 3a.

The total amount of the resin, solvent, and additive in the ink composition may be 15 mass % or more but 60 mass % or less relative to the total amount of the ink composition. In this case, since the ink has excellent coating properties, an excellent light diffusion layer 3a is easily formed, and an increase in ink viscosity and deterioration of drying properties of the light diffusion layer 3a due to the presence of excessive resin are easily prevented.

The ratio of the resin to the total amount of the resin, solvent, and additive is not particularly limited and is preferably 50 mass % or less. The ratio of the additive to the total amount of the resin, solvent, and additive is also not particularly limited and is preferably 10 mass % or less.

The light diffusion layer 3a can be formed by applying the ink composition directly to the interconnector 1 and drying the resulting film. When the light diffusion layer 3a is formed using the ink composition, the light diffusion layer 3a itself has an adhesive function, and is thus adhered to the interconnector 1 without providing the adhesion layer 3b as is shown provided in the embodiment of FIG. 1. In such a manner, the light diffusion members 3 are disposed on the interconnectors 1. The thickness of the light diffusion layer 3a is the same as that in the embodiment of FIG. 1. The light diffusion members 3 formed using the ink composition have the same performance as that of the light diffusion members 3 formed from the resin molded article described above, and preferable embodiments of the light diffusion members 3 formed using the ink composition are the same as those of the light diffusion members 3 formed from the resin molded article described above.

Since the light diffusion members 3 formed in the above manner have the same light diffusion function as that in the embodiment of FIG. 1, a solar cell module A comprising interconnectors 1 having the light diffusion members 3 above has excellent power generation efficiency because of the same principle as described above.

In the solar cell module A according to the present invention, the types of members other than the light diffusion members 3 are not particularly limited as long as they have been used for solar cells. For example, as the solar cells 6, cells commonly used in crystalline silicon solar cells can be used.

In addition, the solar cell module A can be produced by using a method similar to a conventional method. The method for disposing the light diffusion members 3 on the interconnectors 1 is not particularly limited. For example, when the light diffusion layer 3a is formed from a resin molded article, the light diffusion members 3 can be adhered to the interconnectors 1 by heat pressing, such as heat sealing. When each light diffusion member 3 comprises the light diffusion layer 3a and the adhesion layer 3b, the adhesion layer 3b may be attached to the interconnector 1. When the light diffusion members 3 are disposed on the interconnectors 1 by using an ink composition, the ink composition is applied to the interconnectors 1, followed by drying, thereby forming a film. As the application conditions and drying conditions, those commonly used for film formation can be employed. The interconnectors for solar cells 1 comprising the light diffusion members 3 can be produced by any of the above-described methods.

When the interconnectors 1 are joined to the solar cells 6, the light diffusion members 3 may be generally disposed in advance on the surfaces of the interconnectors 1 on the side opposite to the surfaces that are to be soldered to the light-receiving surfaces of the cells, and then the interconnectors 1 may be joined to the solar cells 6. In this case, the surface of each interconnector 1 on the side opposite to the surface on which the light diffusion member 3 is disposed is soldered to the light-receiving surface of the solar cell 6, and the interconnector 1 is also connected to the non-light-receiving surface of the adjacent solar cell 6. By doing so, in the finished solar cell module A, the light diffusion members 3 are disposed on the side receiving light such as sunlight (on the front surface side of the solar cell module A).

Alternatively, in a string in which each interconnector 1 is soldered to the light-receiving surface of the solar cell 6 and the non-light-receiving surface of the adjacent solar cell 6 beforehand and the plurality of cells is connected in series, the light diffusion members 3 may be joined to the surfaces of the interconnectors 1 on the side opposite to the surfaces soldered to the light-receiving surfaces of the solar cells 6.

In the solar cell module A comprising interconnectors for solar cells 1 comprising the light diffusion members 3, since the light diffusion members 3 have a light diffusion function and a light reflection function, the amount of light received by the solar cells 6 can be further increased in accordance with the principle described above. As a result, the solar cell module A has excellent power generation efficiency.

### EXAMPLES

The present invention is described in more detail below with reference to Examples but is not limited to the embodiments in these Examples.

### Example 1

A light diffusion member for an interconnector (hereinafter abbreviated as “light diffusion member”) comprising a light diffusion layer having a thickness of 50 μm and an adhesion layer having a thickness of 30 μm was produced. The light diffusion layer was produced by melt kneading 75 parts by mass of a polyethylene resin (LLDPE ULT-ZEX 4020L produced by Prime Polymer Co., Ltd.) and 25 parts by mass of a rutile-type titanium oxide having an average particle diameter of 210 nm (CR-63 produced by Ishihara Sangyo Kaisha, Ltd.). In the light diffusion layer, the content of the titanium oxide was 25 wt %. The adhesion layer was produced by melt kneading an adhesive polyolefin resin (Admer LF128 (registered trademark) produced by Mitsui Chemicals, Inc). These light diffusion layer and adhesion layer were co-extruded to obtain a 2-layer co-extruded film that is a laminate of the light diffusion layer and the adhesion layer, as a light diffusion member. This light diffusion member is referred to as “Ti25%-LE50/ad30” in Tables 1 and 2 shown below.

### Example 2

A light diffusion member was obtained in the same manner as in Example 1, except that the thickness of the light diffusion layer was 100 μm. This light diffusion member is referred to as “Ti25%-LE100/ad30” in Tables 1 and 2 shown below.

### Example 3

A light diffusion member was obtained in the same manner as in Example 1, except that the thickness of the light diffusion layer was 150 μm. This light diffusion member is referred to as “Ti25%-LE150/ad30” in Tables 1 and 2 shown below.

### Example 4

A light diffusion member was obtained in the same manner as in Example 1, except that 75 parts by mass of a polypropylene resin (Prime Polypro F-300SP produced by Prime Polymer Co., Ltd.) was used in place of the polyethylene resin and that the thickness of the light diffusion layer was changed to 100 μm. This light diffusion member is referred to as “Ti25%-PP100/ad30” in Tables 1 and 2 shown below.

### Example 5

A light diffusion member was obtained in the same manner as in Example 1, except that the amount of the polyethylene resin was changed from 75 parts by mass to 70 parts by mass, that the thickness of the light diffusion layer was changed to 100 μm, and further that 30 parts by mass of a barium sulfate having an average particle diameter of 300 nm (B-30 produced by Sakai Chemical Industry Co., Ltd.) was used in place of the titanium oxide. In the light diffusion layer, the content of the barium sulfate was 30 wt %. This light diffusion member is referred to as “Ba30%-LE100/ad30” in Tables 1 and 2 shown below.

### Example 6

A light diffusion member comprising a first light diffusion layer having a thickness of 50 μm, a second light diffusion layer having a thickness of 50 μm, and an adhesion layer having a thickness of 30 μm was produced. The first light diffusion layer was produced by melt kneading 70 parts by mass of a polyethylene resin (LLDPE ULT-ZEX 4020L produced by Prime Polymer Co., Ltd.) and 30 parts by mass of a barium sulfate having an average particle diameter of 300 nm (B-30 produced by Sakai Chemical Industry Co., Ltd.). In the first light diffusion layer, the content of the barium sulfate was 30 wt %. The second light diffusion layer was produced by melt kneading 75 parts by mass of a polyethylene resin (LLDPE ULT-ZEX 4020L produced by Prime Polymer Co., Ltd.) and 25 parts by mass of a rutile-type titanium oxide having an average particle diameter of 210 nm (CR-63 produced by Ishihara Sangyo Kaisha, Ltd.). In the second light diffusion layer, the content of the titanium oxide was 25 wt %. The adhesion layer was produced by melt kneading an adhesive polyolefin resin (Admer LF128 (registered trademark) produced by Mitsui Chemicals, Inc). These first light diffusion layer, second light diffusion layer, and adhesion layer were co-extruded to obtain a 3-layer co-extruded film comprising the first light diffusion layer, the second light diffusion layer, and the adhesion layer stacked in this order, as a light diffusion member. This light diffusion member is referred to as “Ba30%-LE50/Ti25%-LE50/ad30” in Tables 1 and 2 shown below.

### Example 7

A light diffusion member comprising a 50-μm-thick light diffusion layer having adhesive properties was produced. The light diffusion layer was produced by melt kneading 60 parts by mass of a polyethylene resin (LLDPE ULT-ZEX 4020L produced by Prime Polymer Co., Ltd.), 15 parts by mass of an adhesive polyolefin resin (Admer LF128 produced by Mitsui Chemicals, Inc), and 25 parts by mass of a rutile-type titanium oxide having an average particle diameter of 210 nm (CR-63 produced by Ishihara Sangyo Kaisha, Ltd.). In the light diffusion layer, the content of the titanium oxide was 25 wt %. This light diffusion member is referred to as “Ti25%-ad15%-LE50” in Tables 1 and 2 shown below.

### Example 8

As a resin, 27 parts by mass of a mixture of an acrylic acid ester monomer and an epoxy resin was prepared; as inorganic particles, 40 parts by mass of a rutile-type titanium oxide and 5 parts by mass of silica were prepared; as a curing agent, 1 part by mass of an amine compound was prepared; as an organic solvent, 25 parts by mass of dipropylene glycol monomethyl ether was prepared; and as an additive, 2 parts by mass of a leveling agent was prepared. These components were mixed and dispersed to obtain an ink composition. After short-circuit current measurement for solar cells (before modularization), described below, the ink composition was applied to an interconnector for solar cells (SSA-SPS produced by Hitachi Cable, Ltd.) that had been soldered to the solar cell, followed by drying, thereby forming a light diffusion member having a thickness after drying of 50 μm on the interconnector. In the light diffusion member, the content of the titanium oxide was 50 wt %. This light diffusion member is referred to as “acrylic ink Ti50%50” in Tables 1 and 2 shown below.

### Example 9

A light diffusion member comprising a first light diffusion layer having a thickness of 30 μm, a second light diffusion layer having a thickness of 70 μm, and an adhesion layer having a thickness of 30 μm was produced. The first light diffusion layer was produced by melt kneading 99 parts by mass of a polyethylene resin and 1 part by mass of a europium (III) complex having a β-diketone and a phosphine oxide as ligands (Eu(TTA)3Phen). In the first light diffusion layer, the content of the phosphor was 1 wt %. The second light diffusion layer was produced by melt kneading 75 parts by mass of a polyethylene resin (LLDPE ULT-ZEX 4020L produced by Prime Polymer Co., Ltd.) and 25 parts by mass of a rutile-type titanium oxide having an average particle diameter of 210 nm (CR-63 produced by Ishihara Sangyo Kaisha, Ltd.). In the second light diffusion layer, the content of the titanium oxide was 25 wt %. The adhesion layer was produced by melt kneading an ionomer adhesive polyolefin resin (Adner LF128 (registered trademark) produced by Mitsui Chemicals, Inc). These first light diffusion layer, second light diffusion layer, and adhesion layer were co-extruded to obtain a 3-layer co-extruded film comprising the first light diffusion layer, second light diffusion layer, and adhesion layer stacked in this order, as a light diffusion member. This light diffusion member is referred to as “phosphor 1%-LE30/Ti25%-LE70/ad30” in Tables 1 and 2 shown below.

### Comparative Example 1

An interconnector for solar cells with no light diffusion member was prepared.

### Comparative Example 2

An acrylic pressure-sensitive adhesive (produced by Sumitomo 3M Limited) was applied to the matte surface of 20-μm-thick aluminum foil with gloss on one side such that the thickness of adhesion layer was 30 μm, followed by drying, thereby obtaining a light diffusion member.

### Comparative Example 3

The glossy surface of 20-μm-thick aluminum foil with gloss on one side was embossed with a diagonal lattice pattern (60 mesh, pattern spacing: 1 mm, pattern depth: 0.2 mm) to obtain aluminum foil embossed with a diagonal lattice pattern. An acrylic pressure-sensitive adhesive (produced by Sumitomo 3M Limited) was applied to the non-embossed surface of the aluminum foil, i.e., the matte surface, to a thickness of 30 μm, followed by drying, thereby obtaining a light diffusion member.

### Measurement of Absorptivity in Light Diffusion Members

The transmittance and reflectance in each light diffusion member before the member was adhered to an interconnector for solar cells were measured with V-570 produced by JASCO Corporation. The absorptivity in the light diffusion member was calculated using these measurement values according to the following equation (1).

Absorptivity=100−(transmittance+reflectance) [%] (1)

In the equation, the transmittance and the reflectance are the average value of the transmittance in the wavelength range of 400 to 800 nm and the average value of the reflectance in the wavelength range of 400 to 800 nm. The reason why the average value of the transmittance in the wavelength range of 400 to 800 nm and the average value of the reflectance in the wavelength range of 400 to 800 nm are used is that, among 400 nm to 1200 nm, which is a light absorption band (wavelength range) contributing to power generation of silicon semiconductor substrates, the visible light region of 400 to 800 nm has high energy density and greatly contributes to power generation of solar cells, as described above.

### Measurement of Light Diffusivity in Light Diffusion Members

The light diffusivity was evaluated based on the measurement values of the color difference in L* value (CIE1976 lightness) of L*a*b* color system with a MA68IINS multi-angle spectrophotometer produced by X-Rite Inc. The L* values at wavelengths were measured at 10 nm intervals in the wavelength range of 400 nm to 700 nm, using 45-degree incident light as a light source. The measurement was performed by placing each of the light diffusion members on the glossy surface of aluminum foil such that measurement light transmitted through the light diffusion member was prevented from picking up variations in color of the surface of the measurement stand.

The light diffusivity in each light diffusion member can be calculated from light distribution of diffusely reflected light when parallel light is emitted from a direction at an angle of 45 degrees with respect to the vertical direction of the light diffusion member. More specifically, the light diffusivity was calculated from the following equation (2) using L* values at reflection angles of 15 degrees, 45 degrees, and 75 degrees.

Light diffusivity={(L*value at a reflection angle of 45 degrees+L*value at a reflection angle of 75 degrees)/2}/L*value at a reflection angle of 15 degrees×100 [%] (2)

When the light diffusivity is 90% or more, parallel light perpendicularly incident on glass for solar cells is likely to be diffused and reflected on the interconnector, indicating that the probability that light diffused and reflected at the glass (toughened glass)/air interface undergoes total reflection is high. When the light diffusivity is 70% or less, diffusion and reflection of light on the interconnector is not sufficient, indicating that the probability that the light undergoes total reflection at the glass/air interface is low. When the light diffusivity is 30% or less, the probability is extremely low.

TABLE 1

| | | | Light | | | | | | | |
|---|---|---|---|---|---|---|---|---|---|---|
| | | | Diffusion | | | | | | | |
| | | | Layer | | | | | | | Light |
| | | | Thickness | Transmittance | Reflectance | Absorptivity | | | | Diffusivity |
| | | Sample Name | [μm] | [%] | [%] | [%] | L*45 | L*75 | L*15 | [%] |
| Example | 1 | Ti25%-LE50/ad30 | 50 | 13 | 86 | 1 | 97 | 97 | 97 | 100 |
| | 2 | Ti25%-LE100/ad30 | 100 | 8 | 91 | 1 | 98 | 98 | 103 | 95 |
| | 3 | Ti25%-LE150/ad30 | 150 | 5 | 94 | 1 | 99 | 99 | 99 | 100 |
| | 4 | Ti25%-PP100/ad30 | 100 | 6 | 93 | 1 | 98 | 98 | 99 | 99 |
| | 5 | Ba30%-LE100/ad30 | 100 | 66 | 30 | 4 | 92 | 89 | 97 | 94 |
| | 6 | Ba30%-LE50/Ti25%- | 100 | 8 | 90 | 2 | 96 | 95 | 96 | 99 |
| | | LE50/ad30 | | | | | | | | |
| | 7 | Ti25%-ad15%-LE50 | 50 | 12 | 87 | 1 | 97 | 97 | 97 | 100 |
| | 8 | Acrylic ink Ti50%50 | 50 | 6 | 91 | 3 | 98 | 98 | 98 | 100 |
| | 9 | Phosphor 1%-LE30/ | 100 | 10 | 89 | 1 | 98 | 98 | 99 | 99 |
| | | Ti25%-LE70/ad30 | | | | | | | | |
| Comparative | 1 | None | — | 0 | 59 | 41 | — | — | — | — |
| Example | 2 | AL20/ad30 | 20 | 0 | 80 | 20 | 56 | 26 | 191 | 22 |
| | 3 | Lattice embossing AL20/ | 20 | 0 | 82 | 18 | 102 | 64 | 147 | 57 |
| | | ad30 | | | | | | | | |

Table 1 shows the average transmittance, average reflectance, average absorptivity, and light diffusivity in the range of 400 to 800 nm in each of the light diffusion members obtained in the Examples and Comparative Examples (in the case of Comparative Example 1, the interconnector).

### Test Example 1

The effect of using each of the light diffusion members obtained in the Examples and Comparative Examples 2 and 3 (in the case of Comparative Example 1, the interconnector) on power generation efficiency of solar cell modules was evaluated. The power generation efficiency of solar cell modules was evaluated by measuring the short-circuit current [A] of each cell before and after modularization.

First, 6-inch polycrystalline silicon semiconductor cells (produced by Kyocera Corporation) in which an interconnector was soldered to a solar cell were prepared, and the short-circuit current of each cell alone was measured with a solar simulator (PXSS4K-1P produced by Iwasaki Electric Co., Ltd.). This measurement value is a short-circuit current before modularization.

Next, each of the light diffusion members obtained in the Examples and Comparative Examples 2 and 3 was individually heat sealed or applied to the top of the interconnectors soldered to the 6-inch polycrystalline silicon semiconductor cells, thereby forming a light diffusion layer.

Solar cell modules were produced with a vacuum laminator by stacking toughened glass, a sealing member, a solar cell, a sealing member, and a rear surface protection sheet, in this order. The short-circuit current in each solar cell module was measured in the same manner as above. The obtained measurement value is a short-circuit current after modularization. The size of the toughened glass was 180 mm square.

The rate of change in the short-circuit current Isc before and after modularization was calculated according to the following equation (3).

Isc change rate=(Isc after modularization−Isc before modularization)/Isc before modularization×100 [%] (3)

TABLE 2

| | | | Test Example 1 | | | Test Example 2 | | |
|---|---|---|---|---|---|---|---|---|
| | | | (one polycrystalline cell) | | | (four single crystalline cells) | | |
| | | | Isc [A] | Isc [A] | Isc | Isc [A] | Isc [A] | Isc |
| | | | before | after | change rate | before | after | change rate |
| | | Sample Name | modularization | modularization | [%] | modularization | modularization | [%] |
| Example | 1 | Ti25%-LE50/ad30 | 8.939 | 9.405 | 5.2 | 5.426 | 5.709 | 5.2 |
| | 2 | Ti25%-LE100/ad30 | 9.002 | 9.526 | 5.8 | 5.465 | 5.778 | 5.7 |
| | 3 | Ti25%-LE150/ad30 | 8.879 | 9.355 | 5.4 | 5.390 | 5.678 | 5.4 |
| | 4 | Ti25%-PP100/ad30 | 9.180 | 9.665 | 5.3 | 5.398 | 5.674 | 5.1 |
| | 5 | Ba30%-LE100/ad30 | 8.893 | 9.363 | 5.3 | 5.436 | 5.713 | 5.1 |
| | 6 | Ba30%-LE50/ Ti25%- | 8.955 | 9.443 | 5.4 | 5.418 | 5.704 | 5.3 |
| | | LE50/ad30 | | | | | | |
| | 7 | Ti25%-ad15%-LE50 | 8.928 | 9.405 | 5.3 | 5.401 | 5.681 | 5.2 |
| | 8 | Acrylic ink Ti50%50 | 8.925 | 9.399 | 5.3 | 5.400 | 5.677 | 5.1 |
| | 9 | Phosphor 1%-LE30/ | 8.933 | 9.470 | 6.0 | 5.427 | 5.756 | 6.1 |
| | | Ti25%-LE70/ad30 | | | | | | |
| Comparative | 1 | None | 9.001 | 9.423 | 4.7 | 5.434 | 5.614 | 3.3 |
| Example | 2 | AL20/ad30 | 8.981 | 9.391 | 4.6 | 5.457 | 5.606 | 2.7 |
| | 3 | Lattice embossing AL20/ | 8.904 | 9.325 | 4.7 | 5.467 | 5.672 | 3.7 |
| | | ad30 | | | | | | |

Table 2 shows the results of Test Example 1. When each of the light diffusion members obtained in the Examples was used, the Isc change rate was high, indicating that excellent power generation efficiency was imparted to the solar cell modules. In contrast, when the interconnector of Comparative Example 1, which does not comprise a light diffusion member, was used, the rate of change in short-circuit current Isc was lower than the cases of the Examples, indicating that power generation efficiency as high as that obtained when each of the members of the Examples was used was not imparted. When each of the light diffusion members obtained in Comparative Examples 2 and 3 was used, the amount of light received by the solar cell was smaller than that when each of the members of the Examples was used, because of light absorption by the aluminum foil and low light diffusivity, and thus the power generation efficiency was poor compared with the cases of the Examples.

### Test Example 2

To further verify power generation efficiency, 4-cell modules in each of which four cells were connected in series were produced by individually heat sealing or applying each of the light diffusion members obtained in the Examples and Comparative Examples 2 and 3 to interconnectors soldered to 5-inch single crystalline silicon semiconductor cells (produced by Panasonic Corporation). The size of the toughened glass was 300 mm square. The rate of change in short-circuit current Isc before and after modularization was measured in the same manner as in Test Example 1, and the power generation efficiency was evaluated.

Table 2 shows the results of Test Example 2. As with the results of Test Example 1, the results of Test Example 2 showed that when each of the light diffusion members obtained in the Examples was used, the Isc change rate was high, indicating that excellent power generation efficiency was imparted to the solar cell modules compared with the cases of Comparative Examples 1 to 3.

As is clear from the results of the Test Examples, when each light diffusion member of the present invention was formed on the interconnector, light diffused and reflected by the light diffusion member underwent total reflection at the toughened glass/air interface and then was incident on the solar cell, resulting in improved power generation efficiency of the solar cell module.

### DESCRIPTION OF REFERENCE NUMERALS

A. Solar Cell Module
1. Interconnector
3. Light Diffusion Member for an Interconnector
3a. Light Diffusion Layer
3b. Adhesion Layer
4. Incident Light
5. Light
6. Solar Cell
7. Toughened Glass
8. Sealing Member
9. Rear Surface Protection Sheet

1. A light diffusion member for an interconnector for connecting adjacent solar cells, the member being disposed on a surface of the interconnector opposite to the solar cells, and the member comprising a light diffusion layer containing a resin and inorganic particles.

2. The light diffusion member for an interconnector according to claim 1, wherein the average absorptivity of visible light in the wavelength range of 400 nm or more but 800 nm or less is 10% or less, and the light diffusivity is 90% or more, the light diffusivity being defined by a value obtained by dividing an average value of an L* value measured at a reflection angle of 45 degrees when the incidence angle is 45 degrees and an L* value measured at a reflection angle of 75 degrees when the incidence angle is 45 degrees by an L* value measured at a reflection angle of 15 degrees when the incidence angle is 45 degrees.

3. The light diffusion member for an interconnector according to claim 1, wherein the resin comprises at least one member selected from the group consisting of ionomers, ethylene-vinyl acetate copolymers, ethylene-vinyl (meth)acrylate copolymers, adhesive polyolefin resins, acrylic resins, urethane resins, silicone resins, and unsaturated polyester resins.

4. The light diffusion member for an interconnector according to claim 1, wherein the light diffusion layer further contains a phosphor.

5. An interconnector for solar cells, the interconnector comprising the light diffusion member for an interconnector according to claim 1.

6. A solar cell module comprising the interconnector for solar cells according to claim 5.

7. The light diffusion member for an interconnector according to claim 2, wherein the resin comprises at least one member selected from the group consisting of ionomers, ethylene-vinyl acetate copolymers, ethylene-vinyl (meth)acrylate copolymers, adhesive polyolefin resins, acrylic resins, urethane resins, silicone resins, and unsaturated polyester resins.

8. The light diffusion member for an interconnector according to claim 2, wherein the light diffusion layer further contains a phosphor.

9. The light diffusion member for an interconnector according to claim 3, wherein the light diffusion layer further contains a phosphor.

10. An interconnector for solar cells, the interconnector comprising the light diffusion member for an interconnector according to claim 2.

11. An interconnector for solar cells, the interconnector comprising the light diffusion member for an interconnector according to claim 3.

12. An interconnector for solar cells, the interconnector comprising the light diffusion member for an interconnector according to claim 4.
